(19) United States
(12) Patent Application Publication
(10) Pub. No.: US 2025/0331111 A1
(43) Pub. Date: Oct. 23, 2025

(54) HOUSING AND VEHICLE

(71) Applicant: Panasonic Automotive Systems Co., Ltd., Kanagawa (JP)

(72) Inventors: Takeshi HONDA, Hyogo (JP); Akinobu NAMIMOTO, Osaka (JP)

(73) Assignee: Panasonic Automotive Systems Co., Ltd., Kanagawa (JP)

(21) Appl. No.: 19/174,384

(22) Filed: Apr. 9, 2025

(30) Foreign Application Priority Data
Apr. 19, 2024 (JP) 2024-068312

(51) Int. Cl. H05K 5/00; B60R 11/02; H04R 3/00

(52) U.S. Cl. CPC H05K 5/0052; B60R 11/0264; H04R 3/00; H04R 2499/13

(57) ABSTRACT

A housing includes: an outer box component including: an outer wall portion including a first wall portion and a second wall portion; and an outer surface portion; an inner box component including: an inner wall portion including a third wall portion and a fourth wall portion; and an inner surface portion; an outer fitting portion provided to the first wall portion; an inner fitting portion provided to the third wall portion; an outer engaging portion provided to the second wall portion; and an inner engaging portion that is provided to the fourth wall portion and that, in a first direction in which the first wall portion and the third wall portion align: when the outer fitting portion and the inner fitting portion are engaged, engages with the outer engaging portion in a direction in which the outer fitting portion and the inner fitting portion move away from each other.

### CROSS REFERENCE TO RELATED APPLICATION

The present application is based on and claims priority of Japanese Patent Application No. 2024-068312 filed on Apr. 19, 2024.

### Field

The present disclosure relates to a housing and a vehicle that includes the housing.

### Background

Conventionally, there has been a method in which, in a housing including a main body and a lid that have been fitted together, the main body and the lid are fixed by a snap-fit. In the housings disclosed in Patent Literature (PTL) 1, 2, 3, and 4, a lid can be pressed onto a main body due to the material or the structural flexibility of the lid or the main body, and the fitted state is maintained due to the material or the structural resiliency of the lid or the main body.

### CITATION LIST

### Patent Literature

PTL 1: Japanese Unexamined Patent Application Publication No. 2004-179280

PTL 2: Japanese Unexamined Patent Application Publication No. 2002-134963

PTL 3: Japanese Unexamined Patent Application Publication No. 2015-085799

PTL 4: Japanese Unexamined Patent Application Publication No. 2012-250697

### SUMMARY

However, the housings respectively disclosed in PTL 1 to 4 can be improved upon.

The present disclosure provides a housing that is capable of achieving further improvement.

A housing according to one aspect of the present disclosure includes: an outer box component including: an outer wall portion that is loop shaped; and an outer surface portion that covers one end surface of the outer wall portion, the outer wall portion including: a first wall portion; and a second wall portion that is disposed at a surface of the outer wall portion that intersects the first wall portion, the second wall portion being contiguous with the first wall portion; an inner box component including: an inner wall portion that is disposed inward of the outer wall portion and is loop shaped; and an inner surface portion that covers one end surface of the inner wall portion, the inner wall portion including: a third wall portion that is disposed to face the first wall portion; and a fourth wall portion that is disposed to face the second wall portion; an outer fitting portion that is provided to the first wall portion; an inner fitting portion that is provided to the third wall portion and engages, by a snap-fit, with the outer fitting portion in a fitting direction, the fitting direction being a direction in which the outer box component and the inner box component are fitted together; an outer engaging portion that is provided to the second wall portion; and an inner engaging portion that is provided to the fourth wall portion and that, in a first direction in which the first wall portion and the third wall portion are aligned with each other: is unengaged with the outer engaging portion during a process of fitting the outer box component and the inner box component together; and when the outer fitting portion and the inner fitting portion are engaged with each other, engages with the outer engaging portion in a direction in which the outer fitting portion and the inner fitting portion move away from each other.

A vehicle according to one aspect of the present disclosure includes: a housing attached to a vehicle main body, wherein the housing includes: an outer box component including: an outer wall portion that is loop shaped; and an outer surface portion that covers one end surface of the outer wall portion, the outer wall portion including: a first wall portion; and a second wall portion that is disposed at a surface of the outer wall portion that intersects the first wall portion, the second wall portion being contiguous with the first wall portion; an inner box component including: an inner wall portion that is disposed inward of the outer wall portion and is loop shaped; and an inner surface portion that covers one end surface of the inner wall portion, the inner wall portion including: a third wall portion that is disposed to face the first wall portion; and a fourth wall portion that is disposed to face the second wall portion; an outer fitting portion that is provided to the first wall portion; an inner fitting portion that is provided to the third wall portion and engages, by a snap-fit, with the outer fitting portion in a fitting direction, the fitting direction being a direction in which the outer box component and the inner box component are fitted together; an outer engaging portion that is provided to the second wall portion; and an inner engaging portion that is provided to the fourth wall portion and that, in a first direction in which the first wall portion and the third wall portion are aligned with each other: is unengaged with the outer engaging portion during a process of fitting the outer box component and the inner box component together; and when the outer fitting portion and the inner fitting portion are engaged with each other, engages with the outer engaging portion in a direction in which the outer fitting portion and the inner fitting portion move away from each other.

The housing and the vehicle according to the present disclosure are capable of achieving further improvement.

### BRIEF DESCRIPTION OF DRAWINGS

These and other advantages and features of the present disclosure will become apparent from the following description thereof taken in conjunction with the accompanying drawings that illustrate a specific embodiment of the present disclosure.

FIG. 1 is a perspective view illustrating a housing to which a bracket has been attached.

FIG. 2 is a perspective view illustrating the housing in an exploded state.

FIG. 3 is a perspective view in which an outer box component has been flipped vertically to illustrate a corner portion.

FIG. 4 is a side view illustrating a state in which the outer box component has been made transparent and the outer box component and an inner box component are being fitted together.

FIG. 5 is a side view illustrating a state in which the outer box component has been made transparent and the outer box component and the inner box component have been fitted together.

FIG. 6 is a side view schematically illustrating a vehicle.

### DESCRIPTION OF EMBODIMENTS

Hereinafter, embodiments of the housing and the vehicle according to the present disclosure will be described with reference to the drawings. Note that the following embodiments are examples given for describing the present disclosure, and are not intended to limit the present disclosure. For example, shapes, structures, materials, constituent elements, relative positional relationships, connection states, numerical values, mathematical formulae, contents of each stage in a method, orders of each stage, and the like illustrated in the following embodiments are examples, and matters not described hereinafter may be included in the present disclosure. Furthermore, geometrical expressions such as parallel and orthogonal may be used, but these expressions do not indicate mathematical rigor and include substantially permissible errors, deviations, and the like. Moreover, expressions such as simultaneous and identical also include a substantially permissible range.

Furthermore, the drawings are schematic views in which emphasis, omission, and ratio adjustment have been appropriately performed in order to describe the present disclosure, and may be different from the actual shapes, positional relationships, and ratios. Moreover, the X-axis, Y-axis, and Z-axis that may be indicated in the drawings indicate rectangular coordinates set arbitrarily for describing the drawings. In other words, the Z-axis is not limited to being an axis that extends in the vertical direction, and the X-axis and the Y-axis do not necessarily exist within a horizontal plane.

Further, hereinafter, a plurality of aspects may be comprehensively described as one embodiment. Moreover, some of the matters described hereinafter are described as optional constituent elements relating to the present disclosure.

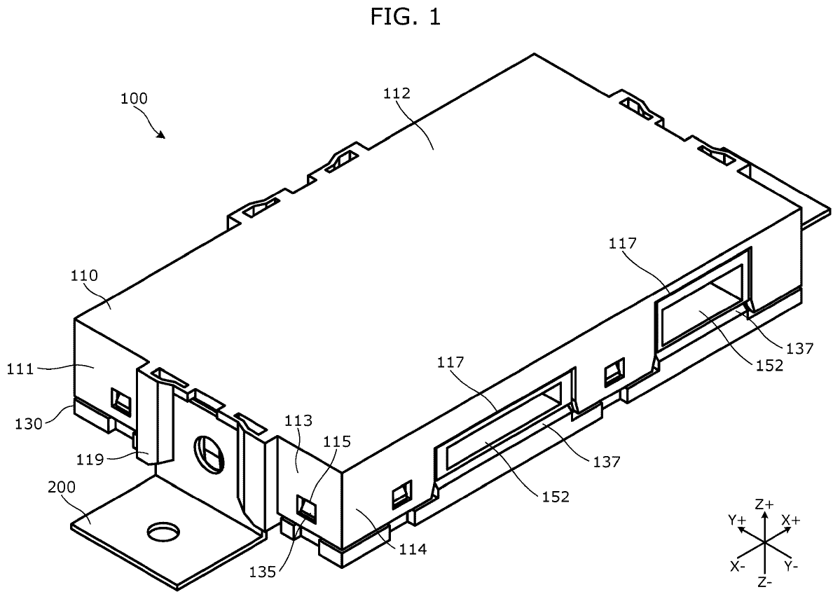

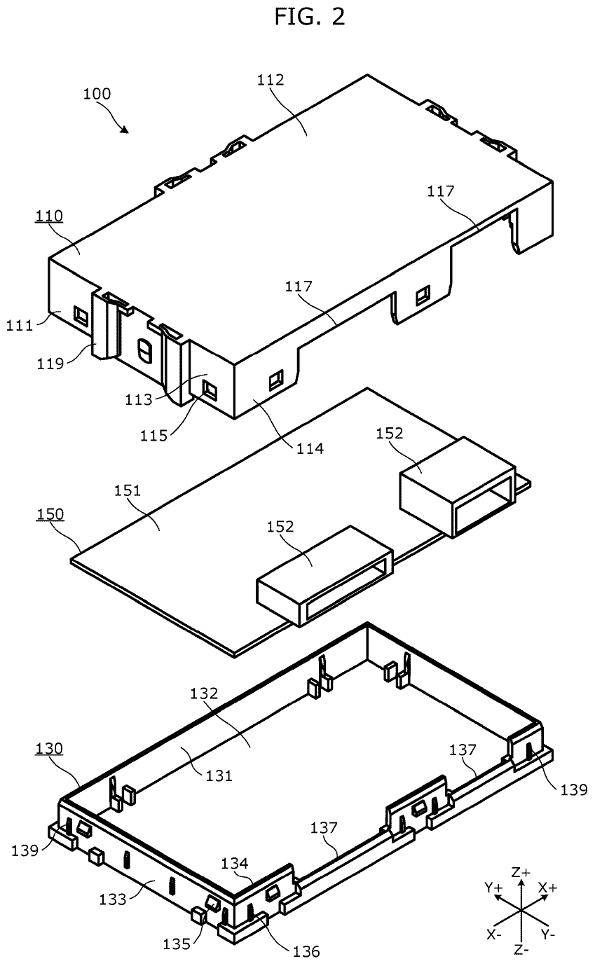

FIG. 1 is a perspective view illustrating housing 100 to which bracket 200 has been attached. FIG. 2 is a perspective view illustrating housing 100 in an exploded state. Housing 100 protects a component housed inside housing 100, and includes outer box component 110 and inner box component 130.

The component housed in housing 100 is not to be construed as limited. In the case of the present embodiment, housing 100 houses circuit board 150. Circuit board 150 includes printed board 151 that has been wired, and circuit components such as an electronic component and an electric component that are mounted on printed board 151. The type of circuit formed by the circuit component electrically connected by circuit board 150 is not limited, and in the case of the present embodiment, an acoustic circuit related to at least one of active noise control or active sound control is formed.

As illustrated in FIG. 1 and FIG. 2, to circuit board 150 is attached exposed component 152, which is a component that is attached to circuit board 150 and penetrates housing 100 from the inner side of housing 100 toward the outer side of housing In the case of the present embodiment, exposed 100. component 152 is a connector for communication from outside of housing 100, the supply of power, and the obtaining of a signal from a sensor. In the case of the present embodiment, to circuit board 150 are attached two exposed components 152. The shape of circuit board 150 is not limited, and in the case of the present embodiment, circuit board 150 is in a rectangular plate shape.

Outer surface portion 112 is a portion that covers the open face on one end of loop-shaped outer wall portion 111. In the case of the present embodiment, outer surface portion 112 is in a rectangular plate shape, and outer wall portion 111, which is in a rectangular loop shape, juts from the peripheral edge of outer surface portion 112.

Outer box component 110 is a component that forms housing 100 by being fitted together with inner box component 130, and includes outer wall portion 111 and outer surface portion 112. In the case of the present embodiment, outer box component 110 functions as a lid.

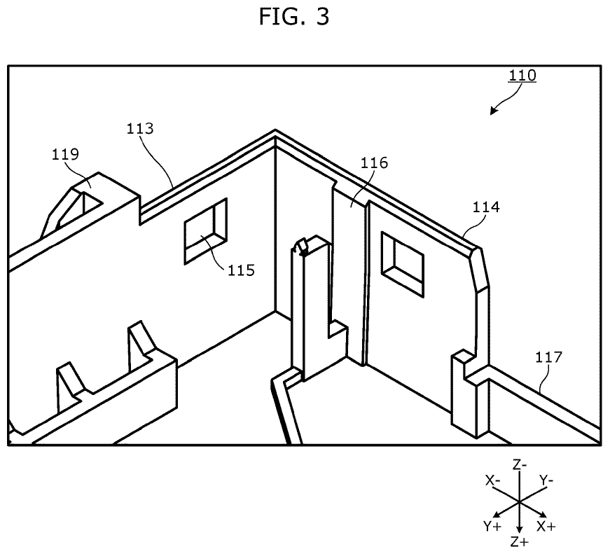

Outer wall portion 111 is a loop-shaped portion that juts in a wall shape from outer surface portion 112. In the case of the present embodiment, outer wall portion 111 is in a rectangular loop shape. FIG. 3 is a perspective view in which outer box component 110 has been flipped vertically to illustrate a corner portion. Outer wall portion 111 includes: first wall portion 113; and second wall portion 114 that is disposed at a surface of outer wall portion 111 that intersects first wall portion 113 (in the case of the present embodiment, a surface of outer wall portion 111 that is orthogonal to first wall portion 113), second wall portion 114 being contiguous with first wall portion 113.

First wall portion 113 includes outer fitting portion 115 that constitutes a snap-fitting structure. In the case of the present embodiment, outer fitting portion 115 is a rectangular hole that penetrates first wall portion 113 in a thickness direction of first wall portion 113. The outer side of first wall portion 113 includes attaching portion 119 for attaching housing 100 to a target. In the case of the present embodiment, housing 100 is attached to the target via bracket 200, which is inserted into attaching portion 119.

Second wall portion 114 includes outer engaging portion 116. The shape of outer engaging portion 116 is not limited. In the case of the present embodiment, outer engaging portion 116 is a strip-shaped protrusion that projects from the inner surface of second wall portion 114 toward fourth wall portion 134 and extends in a fitting direction, the fitting direction being a direction in which outer box component 110 and inner box component 130 are fitted together (in the drawings, the Z-axis direction). Furthermore, second wall portion 114 includes outer frame portion 117, through which exposed component 152 is inserted. Outer frame portion 117 is disposed at a position that is farther, in a first direction (in the drawings, the X-axis direction), from outer fitting portion 115 than outer engaging portion 116 is, the first direction being the direction in which first wall portion 113 and third wall portion 133 are aligned. The shape of outer frame portion 117 is not limited, and is a shape that extends along the outer circumferential surface of exposed component 152. In the case of the present embodiment, outer frame portion 117 forms a notch. Note that outer frame portion 117 may form a through hole.

Inner box component 130 is a component that forms housing 100 by being fitted together with outer box component 110, and includes inner wall portion 131 and inner surface portion 132. In the case of the present embodiment, inner box component 130 functions as a box having one face that is open.

Inner surface portion 132 is a portion that covers the open face on one end of loop-shaped inner wall portion 131. In the case of the present embodiment, inner surface portion 132 is in a rectangular plate shape, and inner wall portion 131, which is in a rectangular loop shape, juts from the peripheral edge of inner surface portion 132.

Inner wall portion 131 is a loop-shaped portion that juts in a wall shape from inner surface portion 132, and is a portion that extends along outer wall portion 111 inward of outer wall portion 111. In the case of the present embodiment, inner wall portion 131 is in a rectangular loop shape that corresponds to outer wall portion 111. Inner wall portion 131 includes: third wall portion 133 that is disposed to face first wall portion 113; and fourth wall portion 134 that is disposed to face second wall portion 114.

First wall portion 133 includes inner fitting portion 135 that constitutes a snap-fitting structure. In the case of the present embodiment, inner fitting portion 135 is provided in a projecting shape from third wall portion 133 toward first wall portion 113. Inner fitting portion 135 engages, by a snap-fit, with outer fitting portion 115 in the fitting direction. In the case of the present embodiment, inner fitting portion 135 is a rectangular protrusion that can be inserted into outer fitting portion 115, and includes a sloping portion whose projection amount decreases toward outer surface portion 112.

Note that the snap-fitting structure is not limited to one site and may be provided to a plurality of sites of first wall portion 113 and third wall portion 133, and may be provided to other portions. Furthermore, outer fitting portion 115 may have a convex structure, and inner fitting portion 135 may have a concave structure (including a through hole).

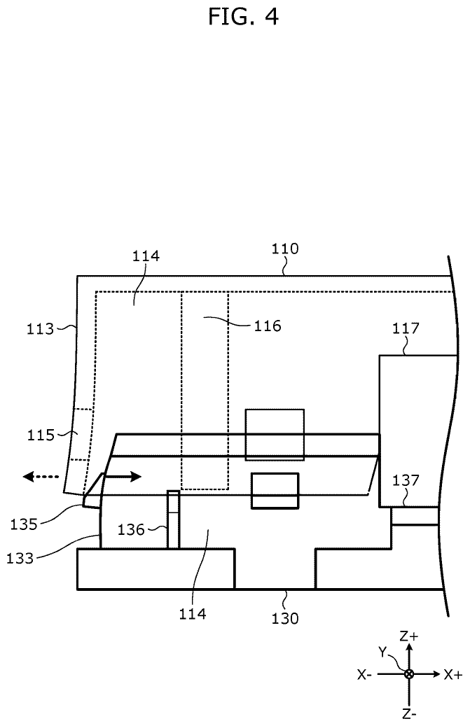

Fourth wall portion 134 includes inner engaging portion 136. Inner engaging portion 136 is a portion that, when outer box component 110 and inner box component 130 have been fitted together, engages with outer engaging portion 116 in the first direction (in the drawings, the X-axis direction). During a process of fitting outer box component 110 and inner box component 130 together, in other words, when, as illustrated in FIG. 4, a part of outer wall portion 111 and a part of inner wall portion 131 are in an overlapping state, inner engaging portion 136 does not engage with outer engaging portion 116. Thus, when the bottom end of first wall portion 113 exceeds inner fitting portion 135, outer engaging portion 116 is not engaged with inner engaging portion 136; therefore, first wall portion 113 is not restricted with regard to elastic deformation in which first wall portion 113 curves outward. Similarly, since inner engaging portion 136 and outer engaging portion 116 are not engaged with each other, third wall portion 133 is not restricted with regard to elastic deformation in which third wall portion 133 curves inward.

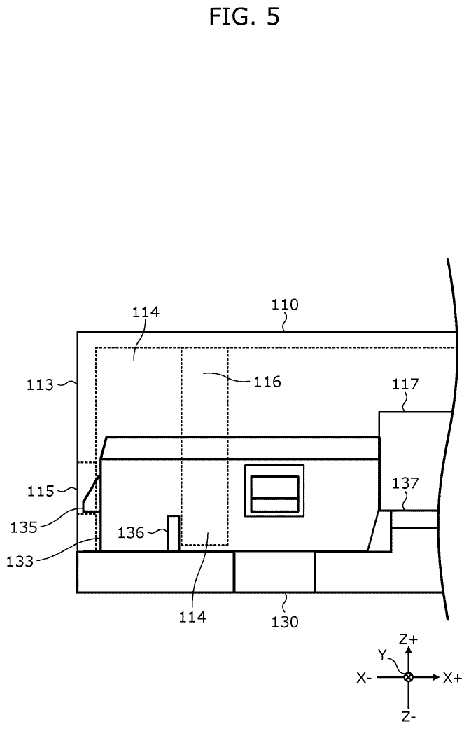

Subsequently, as shown in FIG. 5, when outer fitting portion 115 and inner fitting portion 135 are engaged with each other, that is, when outer fitting portion 115 and inner fitting portion 135 have been snap-fitted together, outer engaging portion 116 and inner engaging portion 136 engage with each other in a direction (in the drawings, the X-axis direction) in which outer fitting portion 115 and inner fitting portion 135 move away from each other. Therefore, when, for example, housing 100 is attached to a target, even when external force is applied to first wall portion 113 from bracket 200, attached to attaching portion 119, in a direction in which outer fitting portion 115 moves away from inner fitting portion 135, outer engaging portion 116 and inner engaging portion 136 in the engaged state can withstand the external force, and the snap-fitted state can be maintained.

Furthermore, fourth wall portion 134 includes inner frame portion 137, through which exposed component 152 is inserted. Inner frame portion 137 is disposed in a position farther away from inner fitting portion 135 than inner engaging portion 136 is, in the first direction (in the drawings, the X-axis direction). The shape of inner frame portion 137 is not limited, and is a shape that follows the outer circumferential surface of exposed component 152. In the case of the present embodiment, inner frame portion 137 forms a notch. Note that inner frame portion 137 may form a through hole.

As illustrated in FIG. 2, in the case of the present embodiment, inner engaging portion 136 is disposed between outer wall portion 111 and inner wall portion 131, and is one of a plurality of determining portions 139 that are protruding and determine a positional relationship (interval) between outer wall portion 111 and inner wall portion 131. In other words, inner engaging portion 136 is a portion that also functions as determining portion 139, and inner engaging portion 136 and at least one determining portion 139 have the same amount of protrusion in the direction toward outer wall portion 111. Note that outer engaging portion 116 may function as determining portion 139.

The material of at least one of outer box component 110 or inner box component 130 is not particularly limited as long as it is a material that has elasticity that allows for forming a snap-fitted state. For example, as the material of the at least one of outer box component 110 or inner box component 130, a resin can be exemplified. Examples of the resin may include acrylonitrile butadiene styrene (ABS), ABS that includes polycarbonate (PC) as an additive, acrylonitrile styrene acrylate (ASA), styrene acrylonitrile (SAN), and polypropylene (PP). Furthermore, the resin may include glass fiber or the like as a reinforcing material. The modulus of elasticity of the specific material constituting housing 100 may be, for example, about 2,000 to 2,500 MPa. This modulus of elasticity may be achieved by adjusting the amount of a substance such as butadiene, acrylic rubber, or the like included in the resin.

Note that the present disclosure is not limited to the above-described embodiment. For example, other embodiments achieved by combining the constituent elements described in the present Description ad libitum or by omitting some of the constituent elements may be included as embodiments of the present disclosure. Moreover, the present disclosure includes variations obtained by various modifications to the above embodiment that can be conceived by those skilled in the art, so long as these various modifications do not depart from the essence of the present disclosure, that is, the intended meaning of the appended Claims.

For example, as illustrated in FIG. 1 and FIG. 2, housing 100 may include, in a wall pair including two walls facing each other, such as first wall portion 113 and third wall portion 133, a plurality of snap-fit structures each including a set of outer fitting portion 115 and inner fitting portion 135. Furthermore, the snap-fit structures may also be disposed to other wall pairs.

Moreover, the engaging structure including outer engaging portion 116 and inner engaging portion 136 may be disposed not only to one end of one wall pair, but also to other ends. Furthermore, the engaging structure may also be disposed to other wall pairs.

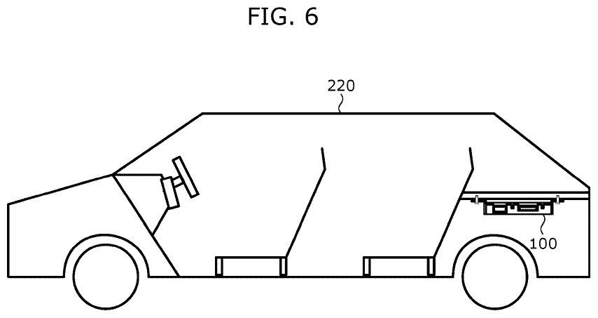

Furthermore, as illustrated in FIG. 6, the present disclosure may be embodied as vehicle 220 that includes housing 100. Examples of vehicle 220 may include an automobile, an aircraft, a marine vessel, and the like. Housing 100 included in vehicle 220 may house circuit board 150 having integrated therein a circuit that realizes: an electronic control unit (ECU) for electronically controlling all or a part of functions of vehicle 220; an audio amplifier; active noise control; active sound control; and/or the like.

### Conclusion

Housing 100 according to a first aspect includes: outer box component 110 including: outer wall portion 111 that is loop shaped; and outer surface portion 112 that covers one end surface of outer wall portion 111, outer wall portion 111 including: first wall portion 113; and second wall portion 114 that is disposed at a surface of outer wall portion 111 that intersects first wall portion 113, second wall portion 114 being contiguous with first wall portion 113; inner box component 130 including: inner wall portion 131 that is disposed inward of outer wall portion 111 and is loop shaped; and inner surface portion 132 that covers one end surface of inner wall portion 131, inner wall portion 131 including: third wall portion 133 that is disposed to face first wall portion 113; and fourth wall portion 134 that is disposed to face second wall portion 114; outer fitting portion 115 that is provided to first wall portion 113; inner fitting portion 135 that is provided to third wall portion 133 and engages, by a snap-fit, with outer fitting portion 115 in a fitting direction, the fitting direction being a direction in which outer box component 110 and inner box component 130 are fitted together; outer engaging portion 116 that is provided to second wall portion 114; and inner engaging portion 136 that is provided to fourth wall portion 134 and that, in a first direction in which first wall portion 113 and third wall portion 133 are aligned with each other: is unengaged with outer engaging portion 116 during a process of fitting outer box component 110 and inner box component 130 together; and when outer fitting portion 115 and inner fitting portion 135 are engaged with each other, engages with outer engaging portion 116 in a direction in which outer fitting portion 115 and inner fitting portion 135 move away from each other.

Due to the first aspect, during the process of fitting outer box component 110 and inner box component 130 together, elastic deformation of first wall portion 113 and third wall portion 133 for forming a snap-fitted state can be permitted without outer engaging portion 116 and inner engaging portion 136 engaging with each other. Since after the snap-fitted state is formed, that is, in the state in which housing 100 has been formed, outer engaging portion 116 and inner engaging portion 136 are engaged with each other, the snap-fitted state can be maintained even when external force is applied to first wall portion 113.

Housing 100 according to a second aspect is housing 100 according to the first aspect, further including: on an outer side of first wall portion 113, attaching portion 119 for attaching housing 100 to a target.

Although external force is applied to first wall portion 113 via attaching portion 119 when housing 100 is attached to a target, the second aspect makes it possible for outer engaging portion 116 and inner engaging portion 136 that have engaged with each other to withstand the external force applied via attaching portion 119; thus, housing 100 of the present disclosure is capable of maintaining the snap-fitted structure.

Housing 100 according to a third aspect is housing 100 according to the first or second aspect, in which housing 100 houses circuit board 150, second wall portion 114 includes outer frame portion 117 through which exposed component 152 is inserted, exposed component 152 being a component that is attached to circuit board 150 and exposed from housing 100, and fourth wall portion 134 includes inner frame portion 137 through which exposed component 152 is inserted.

Although in the wall pair to which outer frame portion 117 and inner frame portion 137 have been disposed, the structural strength is lower than the other wall pairs on which frames are not formed and deformation due to external force tends to occur, the third aspect makes it possible to effectively maintain the snap-fitted state due to outer engaging portion 116 and inner engaging portion 136 being engaged with each other.

Housing 100 according to a fourth aspect is housing 100 according to any one of the first to third aspects, in which at least one of outer engaging portion 116 or inner engaging portion 136 is disposed between outer wall portion 111 and inner wall portion 131 and is one of a plurality of determining portions 139 that are protruding and determine a positional relationship between outer wall portion 111 and inner wall portion 131.

The fourth aspect makes it possible to simplify the structure of housing 100 by also imparting the function of determining portion 139 to at least one of outer engaging portion 116 or inner engaging portion 136.

Housing 100 according to a fifth aspect is housing 100 according to any one of the first to fourth aspects, in which an acoustic circuit related to at least one of active noise control or active sound control is provided to circuit board 150.

The fifth aspect is a working example of housing 100.

Housing 100 according to a sixth aspect is housing 100 according to any one of the first to fifth aspects, in which a material of housing 100 includes at least one of acrylonitrile butadiene styrene (ABS), acrylonitrile styrene acrylate (ASA), styrene acrylonitrile (SAN), or polypropylene (PP).

The sixth aspect makes it possible to permit elastic deformation of a wall pair when forming the snap-fitted state.

Housing 100 according to a seventh aspect is housing 100 according to the sixth aspect, in which the material includes a reinforcing material.

The seventh aspect makes it possible to achieve both elastic deformation and the rigidity as housing 100.

Housing 100 according to an eighth aspect is housing 100 according to any one of the first to seventh aspects, in which a modulus of elasticity of a material of housing 100 is selected from a range of at least 2,000 MPa and at most 2,500 MPa.

The eighth aspect makes it possible to secure the strength as housing 100 by facilitating the fitting together of outer box component 110 and inner box component 130 and creating the snap-fitted state.

Vehicle 220 according to a ninth aspect includes housing 100 attached to a main body of vehicle 220, wherein housing 100 includes: outer box component 110 including: outer wall portion 111 that is loop shaped; and outer surface portion 112 that covers one end surface of outer wall portion 111, outer wall portion 111 including: first wall portion 113; and second wall portion 114 that is disposed at a surface of outer wall portion 111 that intersects first wall portion 113, second wall portion 114 being contiguous with first wall portion 113; inner box component 130 including: inner wall portion 131 that is disposed inward of outer wall portion 111 and is loop shaped; and inner surface portion 132 that covers one end surface of inner wall portion 131, inner wall portion 131 including: third wall portion 133 that is disposed to face first wall portion 113; and fourth wall portion 134 that is disposed to face second wall portion 114; outer fitting portion 115 that is provided to first wall portion 113; inner fitting portion 135 that is provided to third wall portion 133 and engages, by a snap-fit, with outer fitting portion 115 in a fitting direction, the fitting direction being a direction in which outer box component 110 and inner box component 130 are fitted together; outer engaging portion 116 that is provided to second wall portion 114; and inner engaging portion 136 that is provided to fourth wall portion 134 and that, in a first direction in which first wall portion 113 and third wall portion 133 are aligned with each other: is unengaged with outer engaging portion 116 during a process of fitting outer box component 110 and inner box component 130 together; and when outer fitting portion 115 and inner fitting portion 135 are engaged with each other, engages with outer engaging portion 116 in a direction in which outer fitting portion 115 and inner fitting portion 135 move away from each other.

Due to the ninth aspect, during the process of fitting together outer box component 110 and inner box component 130 of housing 100 included in vehicle 220, elastic deformation of first wall portion 113 and third wall portion 133 for forming a snap-fitted state can be permitted without outer engaging portion 116 and inner engaging portion 136 engaging with each other. Since after the snap-fitted state is formed, that is, in the state in which housing 100 has been formed, outer engaging portion 116 and inner engaging portion 136 are engaged with each other, the snap-fitted state can be maintained even when external force is applied to first wall portion 113.

While various embodiments have been described herein above, it is to be appreciated that various changes in form and detail may be made without departing from the spirit and scope of the present disclosure as presently or hereafter claimed.

### Further Information about Technical Background to This Application

The disclosure of the following patent application including specification, drawings, and claims is incorporated herein by reference in its entirety: Japanese Patent Application No. 2024-068312 filed on Apr. 19, 2024.

### INDUSTRIAL APPLICABILITY

The present disclosure can be used in a housing to which external force may be applied. Furthermore, the present disclosure can be used in a vehicle such as an automobile, a marine vessel, an aircraft, or the like.

1. A housing comprising:
an outer box component including: an outer wall portion that is loop shaped; and an outer surface portion that covers one end surface of the outer wall portion,
the outer wall portion including: a first wall portion; and a second wall portion that is disposed at a surface of the outer wall portion that intersects the first wall portion, the second wall portion being contiguous with the first wall portion;
an inner box component including: an inner wall portion that is disposed inward of the outer wall portion and is loop shaped; and an inner surface portion that covers one end surface of the inner wall portion,
the inner wall portion including: a third wall portion that is disposed to face the first wall portion; and a fourth wall portion that is disposed to face the second wall portion;
an outer fitting portion that is provided to the first wall portion;
an inner fitting portion that is provided to the third wall portion and engages, by a snap-fit, with the outer fitting portion in a fitting direction, the fitting direction being a direction in which the outer box component and the inner box component are fitted together;
an outer engaging portion that is provided to the second wall portion; and
an inner engaging portion that is provided to the fourth wall portion and that, in a first direction in which the first wall portion and the third wall portion are aligned with each other:
is unengaged with the outer engaging portion during a process of fitting the outer box component and the inner box component together; and
when the outer fitting portion and the inner fitting portion are engaged with each other, engages with the outer engaging portion in a direction in which the outer fitting portion and the inner fitting portion move away from each other.

2. The housing according to claim 1, further comprising:
on an outer side of the first wall portion, an attaching portion for attaching the housing to a target.

3. The housing according to claim 1, wherein
the housing houses a circuit board,
the second wall portion includes an outer frame portion through which an exposed component is inserted, the exposed component being a component that is attached to the circuit board and exposed from the housing, and
the fourth wall portion includes an inner frame portion through which the exposed component is inserted.

4. The housing according to claim 1, wherein
at least one of the outer engaging portion or the inner engaging portion is disposed between the outer wall portion and the inner wall portion and is one of a plurality of determining portions that are protruding and determine a positional relationship between the outer wall portion and the inner wall portion.

5. The housing according to claim 3, wherein
an acoustic circuit related to at least one of active noise control or active sound control is provided to the circuit board.

6. The housing according to claim 1, wherein
a material of the housing includes at least one of acrylonitrile butadiene styrene (ABS), acrylonitrile styrene acrylate (ASA), styrene acrylonitrile (SAN), or polypropylene (PP).

7. The housing according to claim 6, wherein
the material includes a reinforcing material.

8. The housing according to claim 1, wherein
a modulus of elasticity of a material of the housing is selected from a range of at least 2,000 MPa and at most 2,500 MPa.

9. A vehicle comprising:
a housing attached to a vehicle main body, wherein
the housing includes:
an outer box component including: an outer wall portion that is loop shaped; and an outer surface portion that covers one end surface of the outer wall portion,
the outer wall portion including: a first wall portion; and a second wall portion that is disposed at a surface of the outer wall portion that intersects the first wall portion, the second wall portion being contiguous with the first wall portion;
an inner box component including: an inner wall portion that is disposed inward of the outer wall portion and is loop shaped; and an inner surface portion that covers one end surface of the inner wall portion,
the inner wall portion including: a third wall portion that is disposed to face the first wall portion; and a fourth wall portion that is disposed to face the second wall portion;
an outer fitting portion that is provided to the first wall portion;
an inner fitting portion that is provided to the third wall portion and engages, by a snap-fit, with the outer fitting portion in a fitting direction, the fitting direction being a direction in which the outer box component and the inner box component are fitted together;
an outer engaging portion that is provided to the second wall portion; and
an inner engaging portion that is provided to the fourth wall portion and that, in a first direction in which the first wall portion and the third wall portion are aligned with each other:
is unengaged with the outer engaging portion during a process of fitting the outer box component and the inner box component together; and
when the outer fitting portion and the inner fitting portion are engaged with each other, engages with the outer engaging portion in a direction in which the outer fitting portion and the inner fitting portion move away from each other.
